(19) United States
(12) Patent Application Publication
(10) Pub. No.: US 2026/0136533 A1
(43) Pub. Date: May 14, 2026

(54) SEMICONDUCTOR MEMORY DEVICE AND METHOD OF MANUFACTURING THE SAME

(71) Applicant: Samsung Electronics Co., Ltd., Suwon-si (KR)

(72) Inventors: Seunghoon Kim, Suwon-si (KR); Hyunjin Lee, Suwon-si (KR); Sujin Kang, Suwon-si (KR); Yongkwan Kim, Suwon-si (KR); Huijung Kim, Suwon-si (KR); Heejae Chae, Suwon-si (KR)

(21) Appl. No.: 19/298,907

(22) Filed: Aug. 13, 2025

(30) Foreign Application Priority Data
Nov. 12, 2024 (KR) 10-2024-0160490

(51) Int. Cl. H10B 12/00

(52) U.S. Cl. CPC H10B 12/315; H10B 12/05

(57) ABSTRACT

A semiconductor memory device includes a plurality of memory cell blocks including a plurality of vertical channel transistors and a boundary region surrounding each of the plurality of memory cell blocks in a planar view. The semiconductor device includes a first device isolation layer facing the plurality of vertical channel transistors in a first horizontal direction in the boundary region and a second device isolation layer apart from the plurality of vertical channel transistors in the first horizontal direction with the first device isolation layer therebetween. The first device isolation layer includes a first portion, a second portion disposed on the first portion, and a step portion disposed on the first portion and extending from an inner wall of the second portion to the second device isolation layer in the first horizontal direction.

### CROSS-REFERENCE TO RELATED APPLICATION

This application is based on and claims priority under 35 USC § 119 to Korean Patent Application No. 10-2024-0160490, filed on Nov. 12, 2024, in the Korean Intellectual Property Office, the disclosure of which is incorporated by reference herein in its entirety.

### BACKGROUND

Due to the advancement of electronics technology, downscaling of semiconductor devices has been progressing rapidly recently. A semiconductor memory device including a transistor having a vertical channel has been proposed as a structure that facilitates miniaturization and high integration of memory cells.

### SUMMARY

A semiconductor memory device with improved structural reliability and a method of manufacturing the same is described.

According to some implementations, there is provided a semiconductor memory device including a plurality of memory cell blocks including a plurality of vertical channel transistors, a boundary region surrounding each of the plurality of memory cell blocks in a planar view, a first device isolation layer facing the plurality of vertical channel transistors in a first horizontal direction in the boundary region, and a second device isolation layer apart from the plurality of vertical channel transistors in the first horizontal direction with the first device isolation layer therebetween, wherein the first device isolation layer includes a first portion, a second portion disposed on the first portion, and a step portion disposed on the first portion and extending from an inner wall of the second portion to the second device isolation layer in the first horizontal direction.

According to some implementations, there is provided a semiconductor memory device including a plurality of conductive lines extending longitudinally in a first horizontal direction and apart from each other in a second horizontal direction perpendicular to the first horizontal direction, a first interlayer insulating layer surrounding the plurality of conductive lines, a plurality of contact plugs arranged at positions apart from the plurality of conductive lines in a vertical direction, a second interlayer insulating layer surrounding the plurality of contact plugs, a plurality of vertical channel transistors between the plurality of conductive lines and the plurality of contact plugs, the plurality of vertical channel transistors including a plurality of channel structures in contact with one selected from the plurality of conductive lines and one selected from the plurality of contact plugs, a first device isolation layer between the first interlayer insulating layer and the second interlayer insulating layer and facing the plurality of vertical channel transistors in the first horizontal direction, and a second device isolation layer apart from the plurality of vertical channel transistors in the first horizontal direction with the first device isolation layer therebetween, wherein the first device isolation layer includes a first portion, a second portion positioned on the first portion, and a step portion positioned on the first portion and extending from an inner wall of the second portion to the second device isolation layer in the first horizontal direction.

According to some implementations, there is provided a semiconductor memory device including a memory cell region including a plurality of memory cell blocks and a boundary region surrounding the plurality of memory cell blocks, a peripheral circuit region surrounding the memory cell region, wherein the semiconductor memory device comprising a plurality of vertical channel transistors arranged in each of the plurality of memory cell blocks; a first device isolation layer facing the plurality of vertical channel transistors in a first horizontal direction in the boundary region; and a second device isolation layer apart from the plurality of vertical channel transistors in the first horizontal direction with the first device isolation layer therebetween, and wherein the first device isolation layer includes a first portion, a second portion positioned on the first portion, and a step portion positioned on the first portion and extending from an inner wall of the second portion to the second device isolation layer in the first horizontal direction.

### BRIEF DESCRIPTION OF THE DRAWINGS

Some implementations will be more clearly understood from the following detailed description taken in conjunction with the accompanying drawings in which:

FIG. 1 is a plan layout diagram schematically illustrating a semiconductor memory device according to some implementations;

FIG. 2 is an enlarged plan view of portion EX1 of FIG. 1;

FIG. 3A is a cross-sectional view taken along line X1-X1′ of FIG. 2;

FIG. 3B is an enlarged cross-sectional view of portion CX1 of FIG. 3A;

FIG. 4A is a cross-sectional view illustrating a semiconductor memory device according to some implementations;

FIG. 4B is an enlarged cross-sectional view of portion CX2 of FIG. 4A;

FIG. 5A is a cross-sectional view illustrating a semiconductor memory device according to some implementations;

FIG. 5B is an enlarged cross-sectional view of portion CX3 of FIG. 5A;

FIG. 6A is a cross-sectional view illustrating a semiconductor memory device according to some implementations;

FIG. 6B is an enlarged cross-sectional view of portion CX4 of FIG. 6A;

FIG. 7A is a cross-sectional view illustrating a semiconductor memory device according to some implementations;

FIG. 7B is an enlarged cross-sectional view of portion CX5 of FIG. 7A;

FIGS. 8 to 17 are cross-sectional views illustrating a method of manufacturing a semiconductor memory device, according to some implementations;

FIGS. 18 to 21 are cross-sectional views illustrating a method of manufacturing a semiconductor memory device, according to some implementations; and

FIG. 22 is a cross-sectional view illustrating a method of manufacturing a semiconductor memory device, according to some implementations.

### DETAILED DESCRIPTION OF THE SOME IMPLEMENTATIONS

Hereinafter, some implementations are described in detail with reference to the accompanying drawings. The same reference numerals are used for identical components in the drawings, and redundant descriptions thereof are omitted.

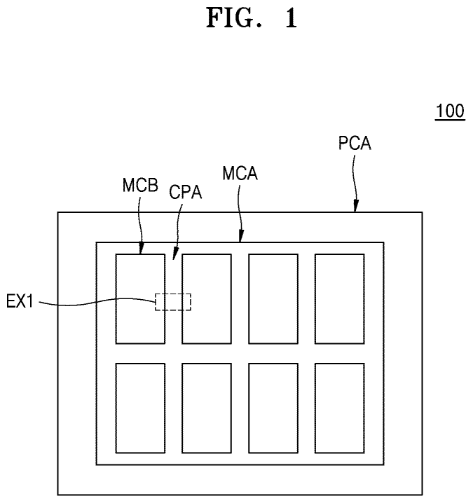

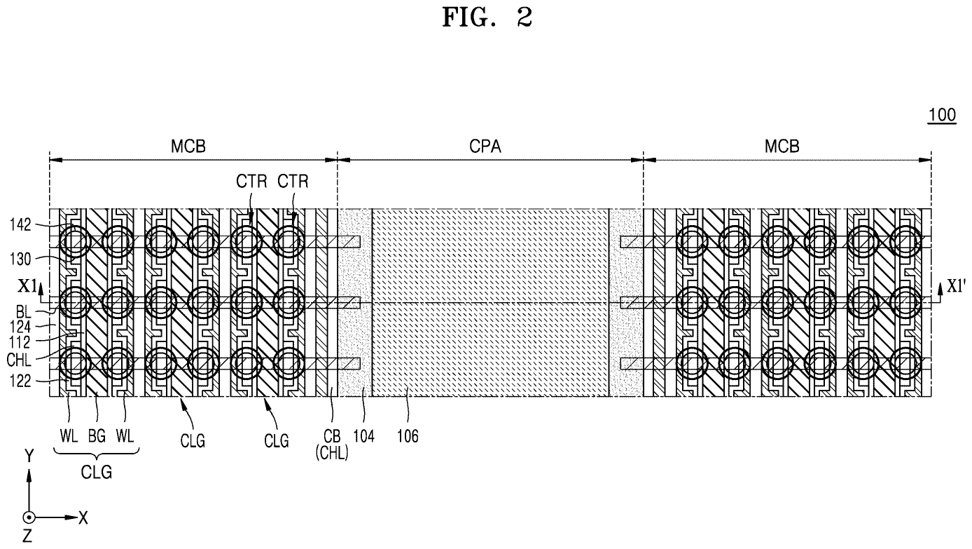

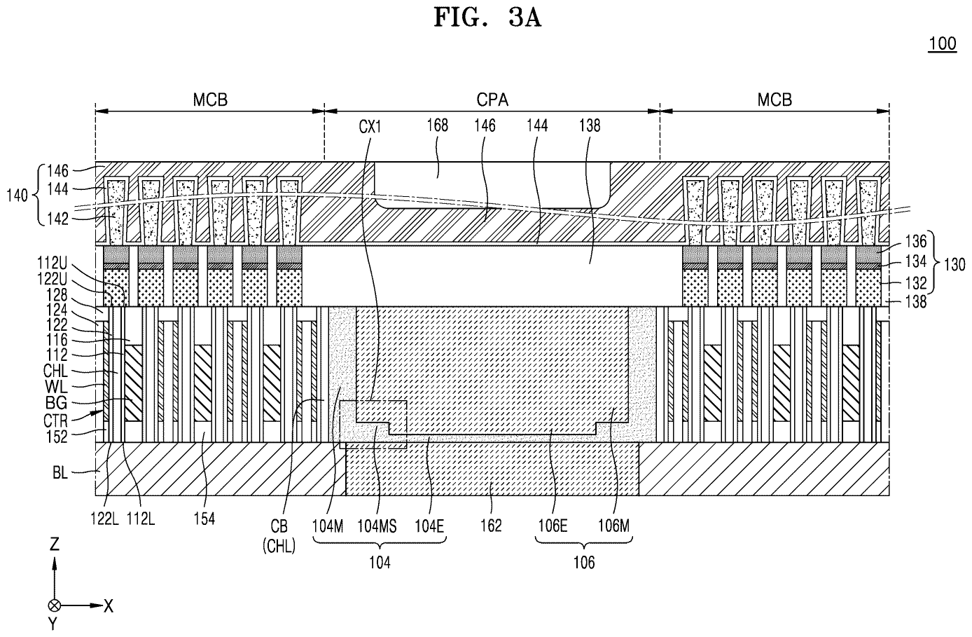

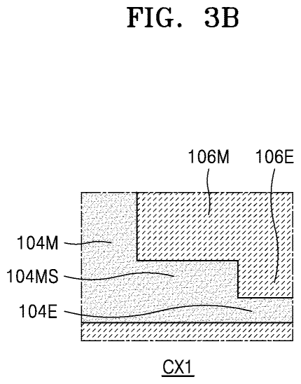

FIG. 1 is a plan layout diagram schematically illustrating a semiconductor memory device 100 according to some implementations. FIG. 2 is an enlarged plan view of portion EX1 of FIG. 1. FIG. 3A is a cross-sectional view taken along line X1-X1′ of FIG. 2. FIG. 3B is an enlarged cross-sectional view of portion CX1 of FIG. 3A.

Referring to FIGS. 1, 2, 3A, and 3B, the semiconductor memory device 100 may include, from a planar perspective, a memory cell region MCA in which a plurality of memory cells are arranged and a peripheral circuit region PCA surrounding the memory cell region MCA. The memory cell region MCA may include a plurality of memory cell blocks MCBs and a boundary region CPA surrounding each of the plurality of memory cell blocks MCBs. A plurality of memory cells may be arranged in each of the memory cell blocks MCBs. The boundary region CPA may mutually insulate each of the memory cell blocks MCBs. In the boundary region CPA, a first device isolation layer 104 and a second device isolation layer 106 may be formed as described below. The peripheral circuit region PCA may include a peripheral circuit transistor. The peripheral circuit transistor may be configured to transmit signals and/or power to each of the memory cells arranged in the memory cell region MCA. For example, the peripheral circuit transistor may configure various circuits, such as a command decoder, control logic, address buffer, row decoder, column decoder, sense amplifier, and data input/output circuit.

A plurality of conductive lines BLs may be elongated in each of the memory cell blocks MCBs in a first horizontal direction (an X direction) and may be apart from each other in a second horizontal direction (a Y direction). Each of the conductive lines BL is arranged in the memory cell blocks MCBs and may extend to a boundary region CPA. In the semiconductor memory device 100, the conductive lines BL may form a bit line. Each of the memory cells MCBs may be apart from each other in the first horizontal direction (the X direction) or a second horizontal direction (the Y direction) with a first interlayer insulating layer 162 therebetween.

In some implementations, the conductive lines BL may each include a metal, a conductive metal nitride, a metal silicide, doped polysilicon, or combinations thereof. For example, the conductive lines BL may each include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or combinations thereof.

In some implementations, the first interlayer insulating layer 162 may include a silicon oxide film, a silicon nitride film, or combinations thereof.

A plurality of channel structures CHL may be arranged on the conductive lines BL, and a plurality of contact plugs 130 may be arranged on the channel structures CHL. In some implementations, the channel structures CHL may be repeatedly arranged apart from each other in the first horizontal direction (the X direction) and the second horizontal direction (the Y direction) on the conductive lines BL. Each of the contact plugs 130 may be placed on a corresponding channel structure CHL among the channel structures CHL. Each of the channel structures CHL may extend in a vertical direction (a Z direction) between one selected from the conductive lines BL and one selected from the contact plugs 130. Among the channel structures CHL, the channel structure CHL located closest to the boundary region CPA may be named a boundary channel structure CB.

According to some implementations, an upper surface of each of the channel structures CHL may be connected to one contact plug 130 selected from the contact plugs 130, and a lower surface of each of the channel structures CHL may be connected to one conductive line BL selected from the conductive lines BL. In some implementations, the channel structure CHL may include a conductive region, for example, a well doped with impurities or a structure doped with impurities. Each of the channel structures CHL may have an impurity region formed that functions as a source/drain region.

In some implementations, the channel structures CHL may each include silicon, for example, single crystal silicon, polycrystalline silicon, or amorphous silicon. In other some implementations, the channel structures CHL may each include at least one selected from Ge, SiGe, SiC, GaAs, InAs, and InP.

The contact plugs 130 may be apart in the vertical direction (the Z direction) from the conductive lines BL with the channel structures CHL therebetween. The contact plugs 130 may be arranged in a matrix arrangement so as to be mutually apart in the first horizontal direction (the X direction) and the second horizontal direction (the Y direction). The contact plugs 130 may be connected to the channel structures CHL, respectively.

In some implementations, the contact plugs 130 may each include a metal, a conductive metal nitride, a metal silicide, doped polysilicon, or combinations thereof. For example, the contact plugs 130 may each include Ti, TiN, Ta, TaN, Mo, Ru, W, WN, Co, Ni, TiSi, TiSiN, WSi, WSiN, TaSi, TaSiN, RuTiN, CoSi, NiSi, doped polysilicon, or combinations thereof.

In some implementations, the contact plugs 130 may each include a first conductive pattern 132, a second conductive pattern 134, and a third conductive pattern 136 sequentially stacked on the channel structures CHL, as illustrated in FIG. 3A. For example, the first conductive pattern 132 may include doped polysilicon, the second conductive pattern 134 may include metal silicide, and the third conductive pattern 136 may include metal, but implementations are not limited thereto.

Each of the contact plugs 130 may be surrounded by a second interlayer insulating layer 138. Each of the contact plugs 130 may extend through the second interlayer insulating layer 138 and contact the selected one channel structure CHL. The contact plugs 130 may be apart from each other in the first horizontal direction (the X direction) and the second horizontal direction (the Y direction) with the second interlayer insulating layer 138 therebetween.

In some implementations, the second interlayer insulating layer 138 may include a silicon oxide film, a silicon nitride film, or combinations thereof.

In the memory cell region MCA, a plurality of back gate electrodes BG and a plurality of word lines WL may be arranged on each of the conductive lines BL. The back gate electrodes BG and the word lines WL may extend longitudinally in the second horizontal direction (the Y direction) between the conductive lines BL and the contact plugs 130, respectively. The back gate electrodes BG and the word lines WL may be apart from each other in the first horizontal direction (the X direction). In some implementations, one back gate electrode BG selected from among the back gate electrodes BG and two word lines WL positioned adjacent to one back gate electrode BG among the word lines WL and apart from each other in the first horizontal direction (the X direction) with one back gate electrode BG therebetween may form one conductive line group CLG. In some implementations, a plurality of conductive line groups CLG on the conductive lines BL may be arranged apart from each other in the first horizontal direction (the X direction) with an isolation insulating pattern 124 therebetween. For example, between each of the back gate electrodes BG, a pair of word lines WL may be arranged apart from each other in the first horizontal direction (the X direction) with the isolation insulating pattern 124 therebetween, each of which belongs to a different conductive line group CLG.

In some implementations, each of the channel structures CHL may be disposed between one back gate electrode BG and one word line WL that are adjacent to each other in the first horizontal direction (the X direction) on a corresponding conductive line BL among the conductive lines BL. In some implementations, a pair of channel structures CHL may be arranged on opposite sides of each of the back gate electrodes BG in the first horizontal direction (the X direction), and a pair of word lines WL may be arranged apart from each of the plurality of back gate electrodes BG with the pair of channel structures CHL therebetween.

In some implementations, a plurality of pairs of channel structures CHL may be arranged in the second horizontal direction (the Y direction), while covering both sidewalls of one back gate electrode BG in the first horizontal direction (the X direction). For example, the plurality of pairs of channel structures CHL may be arranged apart from each other in the second horizontal direction (the Y direction) on corresponding conductive lines BL among the conductive lines BL. Among two word lines WL constituting each of the conductive line groups CLG, one word line WL may cover channel structures CHL covering one sidewall of the back gate electrode BG among the plurality of pairs of channel structures CHL, and the other word line WL among the two word lines WL may cover channel structures CHL covering the other sidewall facing one sidewall of the back gate electrode BG among the plurality of pairs of channel structures CHL. In some implementations, each of the channel structures CHL may face one back gate electrode BG on one side and face one word line WL on the other side facing the one side in the first horizontal direction (the X direction).

In some implementations, the back gate electrodes BG may each include a metal, a conductive metal nitride, doped polysilicon, or combinations thereof. For example, the back gate electrodes BG may include, but are not limited to, Ti, TiN, Ta, TaN, Mo, Ru, W, WN, TiSiN, WSiN, doped polysilicon, or combinations thereof.

In some implementations, the word lines WL may each include a metal, a conductive metal nitride, or combinations thereof. For example, the word lines WL may each include, but are not limited to, Ti, TiN, Ta, TaN, Mo, Ru, W, WN, TiSiN, WSiN, or combinations thereof.

A plurality of back gate dielectric films 112 may cover both sidewalls facing each other in the first horizontal direction (the X direction) of each of the back gate electrodes BG. The back gate dielectric films 112 may be between one back gate electrode BG and one channel structure CHL adjacent to the one back gate electrode BG. The back gate dielectric films 112 may each be in contact with one back gate electrode BG and one channel structure CHL. Each of the back gate dielectric films 112 may include a first surface 112U that contacts each of the contact plugs 130 and a second surface 112L that contacts the conductive lines BL. For example, the back gate dielectric films 112 may have the first surface 112U and the second surface 112L that are opposite to each other in the vertical direction (the Z direction), and the first surfaces 112U may be in contact with the first conductive pattern 132 of each of the contact plugs 130, and the second surface 112L may be in contact with each of the conductive lines BL.

A first capping insulating pattern 116 may be between the back gate electrode BG and each of the contact plugs 130, and a second capping insulating pattern 154 may be between the back gate electrode BG and the conductive line BL. The first capping insulating pattern 116, the back gate electrode BG, and the second capping insulating pattern 154 may overlap in the vertical direction (the Z direction). The opposite sidewalls of each of the first capping insulating pattern 116, the back gate electrode BG, and the second capping insulating pattern 154 facing each other in the first horizontal direction (the X direction) may be in contact with the back gate dielectric film 112 and covered by the back gate dielectric film 112. The back gate electrode BG may be apart from the contact plugs 130 with the first capping insulating pattern 116 therebetween in the vertical direction (the Z direction), and the back gate electrode BG may be apart from the conductive lines BL with the second capping insulating pattern 154 therebetween in the vertical direction (the Z direction). In some implementations, the first capping insulating pattern 116 and the second capping insulating pattern 154 may each include a silicon oxide film, a silicon nitride film, or combinations thereof.

A gate dielectric film 122 may be between each of the word lines WL and the channel structures CHL. The gate dielectric film 122 may be between one word line WL and channel structures CHL positioned adjacent to the one word line WL and arranged in the second horizontal direction (the Y direction) and may be in contact with the one word line WL and the channel structures CHL. The gate dielectric film 122 may include a first surface 122U that contacts each of the contact plugs 130 and a second surface 122L that contacts the conductive lines BL. For example, the gate dielectric film 122 may have the first surface 122U and the second surface 122L that are opposite to each other in the vertical direction (the Z direction), the first surface 122U may be in contact with the first conductive pattern 132 of each of the contact plugs 130, and the second surface 122L may be in contact with each of the conductive lines BL.

In some implementations, the second surface 122L of the gate dielectric film 122, the second surface 112L of the back gate dielectric film 112, and a lower surface of a first portion 104E of the first device isolation layer 104 may be located on the same plane.

One sidewall of each of the channel structures CHL may be in contact with one selected from the back gate dielectric films 112, and the other sidewall of each of the channel structures CHL facing the one sidewall in the first horizontal direction (the X direction) may be in contact with one selected from a plurality of gate dielectric films 122. Opposite sidewalls of each of the channel structures CHL facing each other in the second horizontal direction (the Y direction) may be in contact with a corresponding gate dielectric film 122 among the gate dielectric films 122 and may face a corresponding word line WL among the word lines WL with the gate dielectric film 122 therebetween.

The isolation insulating pattern 124 may be between a pair of word lines WL arranged between a pair of adjacent channel structures CHL. A first buried insulating pattern 128 may be positioned between the pair of word lines WL and the contact plugs 130, and a second buried insulating pattern 152 may be positioned between the pair of word lines WL and the conductive line BL. The pair of second buried insulating patterns 152 may be apart from each other with the isolation insulating pattern 124 therebetween in the first horizontal direction (the X direction). Between a pair of adjacent channel structures CHL, the pair of word lines WL, the first buried insulating pattern 128, and the pair of second buried insulating patterns 152 may overlap in the vertical direction (the Z direction). The pair of word lines WL may be apart from the contact plugs 130 with the first buried insulating pattern 128 therebetween in the vertical direction (the Z direction). The pair of word lines WL may be apart from the conductive lines BL with the pair of second buried insulating patterns 152 therebetween.

In some implementations, the first buried insulating pattern 128 and the second buried insulating pattern 152 may each include a silicon oxide film, a silicon nitride film, or combinations thereof.

In some implementations, the isolation insulating pattern 124 may include a silicon oxide film, a silicon nitride film, or combinations thereof. In some implementations, the isolation insulating pattern 124 may include a different material than the first device isolation layer 104. For example, the isolation insulating pattern 124 may include a silicon oxide film, and the first device isolation layer 104 may include silicon nitride. The isolation insulating pattern 124 may include the same material as that of the first device isolation layer 104. For example, the isolation insulating pattern 124 and the first device isolation layer 104 may include silicon nitride. When the isolation insulating pattern 124 includes the same material as that of the first device isolation layer 104, in the manufacturing process of the semiconductor memory device 100 described below, the isolation insulating pattern 124 may function as a stop film for a second planarization process together with the first portion 104E of the first device isolation layer 104.

In some implementations, the gate dielectric film 122 and the back gate dielectric film 112 may each include a silicon oxide film, a high-k film, or combinations thereof. The “high-k film” may refer to a film having a higher dielectric constant than that of a silicon oxide film. In some implementations, the gate dielectric film 122 and the back gate dielectric film 112 may each include at least one selected from silicon oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

The back gate electrodes BG, the word lines WL, the channel structures CHL, the back gate dielectric films 112, and the gate dielectric films 122 arranged between the conductive lines BL and the contact plugs 130 may form a plurality of vertical channel transistors CTR.

In FIG. 3A, upper surfaces of the back gate electrodes BG are illustrated as being arranged closer to the conductive lines BL than the upper surfaces of the word lines WL, but implementations are not limited thereto. For example, the upper surfaces of the back gate electrodes BG may be arranged at the same vertical level as that of the upper surfaces of the word lines WL or may be arranged closer to the contact plugs 130 than the upper surfaces of the word lines WL.

A capacitor structure 140 may be placed on the contact plugs 130 and the second interlayer insulating layer 138. The capacitor structure 140 may include a plurality of lower electrodes 142, a capacitor dielectric film 144 conformally covering the surface of each of the lower electrodes 142, and an upper electrode 146 covering the lower electrodes 142 with the capacitor dielectric film 144 therebetween. The lower electrodes 142 may be arranged on the memory cell blocks MCB, and each of the lower electrodes 142 may be connected to the channel structure CHL through one contact plug 130 selected from the contact plugs 130. The third conductive pattern 136 included in each of the contact plugs 130 may function as a landing pad that one lower electrode 142 selected from the lower electrodes 142 contacts. A portion of the capacitor dielectric film 144 and a portion of the upper electrode 146 may be placed on the boundary region CPA. A portion of the capacitor dielectric film 144 and a portion of the upper electrode 146 disposed on the boundary region CPA may be sequentially stacked on a portion of the second interlayer insulating layer 138 disposed on the boundary region CPA. A portion of the capacitor dielectric film 144, a portion of the upper electrode 146, and a portion of the second interlayer insulating layer 138 positioned on the boundary region CPA may overlap the first device isolation layer 104 and the second device isolation layer 106 described below in the vertical direction (the Z direction).

A portion of the upper electrode 146 positioned on the boundary region CPA may be covered by the upper insulating layer 168. In some implementations, the upper insulating layer 168 may include, but is not limited to, silicon oxide, silicon nitride, or combinations thereof.

In some implementations, the capacitor dielectric film 144 may include a high-k film. The “high dielectric film” may refer to a film having a higher dielectric constant than that of a silicon oxide film. In some implementations, the capacitor dielectric film 144 may include a metal oxide including at least one metal selected from hafnium (Hf), zirconium (Zr), aluminum (Al), niobium (Nb), cerium (Ce), lanthanum (La), tantalum (Ta), and titanium (Ti). In some implementations, the lower electrodes 142 and upper electrodes 146 may each include a metal film, a conductive metal oxide film, a conductive metal nitride film, a conductive metal oxynitride film, or combinations thereof. In some implementations, the lower electrodes 142 and upper electrodes 146 may each include Nb, Nb oxide, Nb nitride, Nb oxynitride, Ti, Ti oxide, Ti nitride, Ti oxynitride, Co, Co oxide, Co nitride, Co oxynitride, Sn, Sn oxide, Sn nitride, Sn oxynitride, or combinations thereof. In other some implementations, the lower electrodes 142 and upper electrodes 146 may each include TaN, TiAlN, TaAlN, V, VN, Mo, MON, W, WN, Ru, RuO₂, SrRuO₃, Ir, IrO₂, Pt, PtO, SRO(SrRuO₃), BSRO((Ba,Sr)RuO₃), CRO(CaRuO₃), LSCO((La,Sr)CoO₃), or combinations thereof. However, the materials constituting each of the lower electrodes 142 and upper electrodes 146 are not limited thereto.

In the boundary region CPA, the first device isolation layer 104 and the second device isolation layer 106 may be sequentially arranged on the conductive lines BL and the second interlayer insulating layer 162. The first device isolation layer 104 and the second device isolation layer 106 may surround the vertical channel transistors CTR arranged in each of the memory cell blocks MCB. The first device isolation layer 104 and the second device isolation layer 106 may mutually insulate each of the memory cell blocks MCB. The first device isolation layer 104 may face the vertical channel transistors CTR in the first horizontal direction (the X direction) in the boundary region CPA. The second device isolation layer 106 may be apart from the vertical transistors CTR with the first device isolation layer 104 therebetween.

The first device isolation layer 104 may include a first portion 104E, a second portion 104M, and a step portion 104 MS.

Herein, the first device isolation layer 104 is defined as being divided into the first portion 104E, the second portion 104M, and the step portion 104 MS, but this is for convenience of description, and the first portion 104E, the second portion 104M, and the step portion 104 MS may be formed integrally during the manufacturing process of the semiconductor memory device 100 described below, and the boundaries between the first portion 104E, the second portion 104M, and the step portion 104 MS may not be apparent.

The first portion 104E may be positioned on the conductive lines BL and the second interlayer insulating layer 162 in the boundary region CPA, and the second portion 104M and the step portion 104 MS may be arranged on the first portion 104E. A pair of second portions 104M and the step portion 104 MS may be apart in the first horizontal direction (the X direction) with the second device isolation layer 106 therebetween, but each of the pair of second portions 104M and the step portion 104 MS may face each other in the first horizontal direction (the X direction).

A lower surface of the first portion 104E may be in contact with the upper surface of each of the conductive lines BL and the upper surface of the second interlayer insulating layer 162, and the upper surface of the first portion 104E may be in contact with the lower surface of the second portion 104M, the lower surface of the step portion 104 MS, and the lower surface of a first portion 106E of the second device isolation layer 106. Opposite sidewalls of the first portion 104E may be in contact with the channel structure CHL that is positioned most adjacent to the boundary region CPA among the channel structures CHL. The lower surface of the first portion 104E may be positioned on the same plane as that of the lower surfaces of the channel structures CHL.

The second portion 104M may extend from the upper surface of the first portion 104E to the lower surface of the second interlayer insulating layer 138 in a vertical direction (the Z direction). The lower surface of the second portion 104M may be in contact with the first portion 104E, and the upper surface of the second portion 104M may be in contact with the second interlayer insulating layer 138. Among the opposite sidewalls of the second portion 104M facing each other in the first horizontal direction (the X direction), an outer sidewall adjacent to the memory cell block MCB may be in contact with the channel structure CHL positioned most adjacent to the boundary region CPA among the channel structures CHL. An inner wall of the second portion 104M facing the outer wall in the first horizontal direction (the X direction) may be in contact with opposite sidewalls of a second portion 106M of the second device isolation layer 106 and an outer wall of the step portion 104 MS.

The step portion 104 MS may extend in the first horizontal direction (the X direction) from the inner wall of the second portion 104M toward the sidewall of the first portion 106E of the second device isolation layer 106. The upper surface of the step portion 104 MS may be in contact with the lower surface of the second portion 106M of the second device isolation layer 106, the lower surface of the step portion 104 MS may be in contact with the upper surface of the first portion 104E, and the inner wall of the step portion 104 MS may be in contact with opposite sidewalls of the first portion 106E of the second device isolation layer 106. The upper surface and inner wall of the step portion 104 MS in contact with the second device isolation layer 106 may be flat surfaces.

The second device isolation layer 106 may include the first portion 106E and the second portion 106M. Herein, the second device isolation layer 106 is defined as being divided into the first portion 106E and the second portion 106M, but this is for convenience of description, and the first portion 106E and the second portion 106M may be formed integrally during the manufacturing process of the semiconductor memory device 100 described below, and a boundary between the first portion 106E and the second portion 106M may not be apparent.

The first portion 106E may be placed on the first portion 104E of the first device isolation layer 104. A lower surface of the first portion 106E may be in contact with the first portion 104E of the first device isolation layer 104, and an upper surface of the first portion 106E may be in contact with the second portion 106M. Opposite sidewalls of the first portion 106E facing each other in the first horizontal direction (the X direction) may be in contact with the inner wall of the step portion 104 MS of the first device isolation layer 104. The lower surface of the first portion 104E of the first device isolation layer 104 may be at a lower vertical level than that of the lower surface of the first portion 106E of the second device isolation layer 106.

The second portion 106M may be placed on the first portion 106E. A central region of the lower surface of the second portion 106M may be in contact with the upper surface of the first portion 106E, and an edge region of the lower surface of the second portion 106M may be in contact with the upper surface of the step portion 104 MS of the first device isolation layer 104. The upper surface of the second portion 106M may be in contact with the lower surface of the second interlayer insulating layer 138. Opposite sidewalls of the second portion 106M facing each other in the first horizontal direction (the X direction) may be in contact with the inner wall of the second portion 104M of the first device isolation layer 104.

A length of the second portion 106M in the first horizontal direction (the X direction) may be greater than a length of the first portion 106E in the first horizontal direction (the X direction).

The first device isolation layer 104 and the second device isolation layer 106 may mutually insulate a plurality of memory cells arranged in each of the memory cell blocks MCB.

In some implementations, the first device isolation layer 104 may include a material different from that of the second device isolation layer 106. For example, the first device isolation layer 104 and the second device isolation layer 106 may have different removal rates in the manufacturing process of the semiconductor memory device 100. For example, the first device isolation layer 104 may include silicon nitride, and the second device isolation layer 106 may include silicon oxide.

The lower surface of the first portion 104E included in the first device isolation layer 104 may function as a stop film in the manufacturing process of the semiconductor memory device 100 described below.

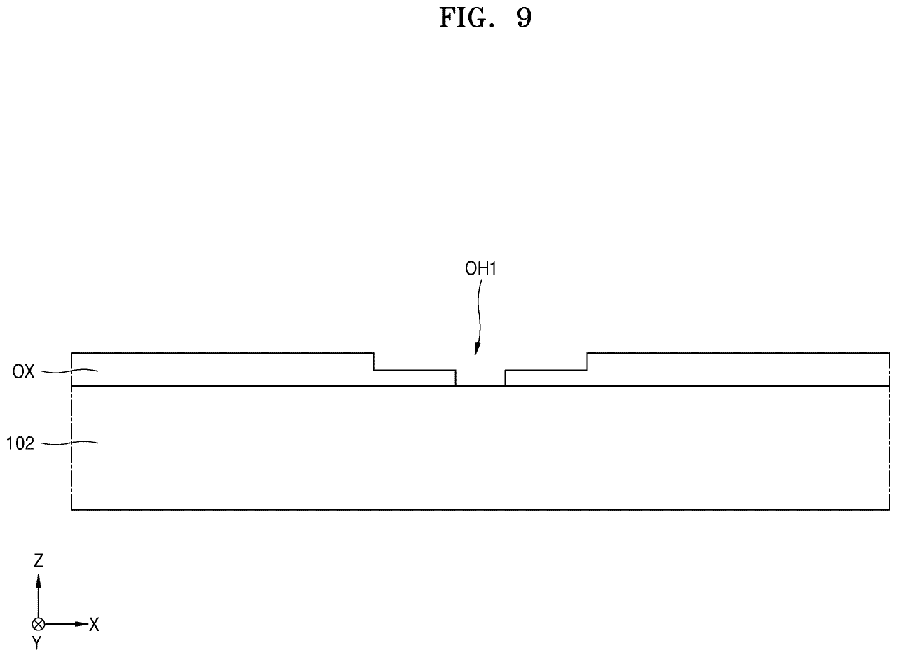

The semiconductor memory device 100 according to some implementations may include the first device isolation layer 104 including the step portion 104 MS and the second device isolation layer 106 placed on the first device isolation layer 104. Here, in the example manufacturing process of the semiconductor memory device 100 described below, an insulating layer OX (see FIG. 9) having a seed zone OH1 (see FIG. 9) having a step structure may be formed on a general substrate, and the first device isolation layer 104 and the second device isolation layer 106 may be formed on the insulating layer OX (see FIG. 9) having the seed zone OH1 (see FIG. 9). Here, the step structure of the insulating layer OX (see FIG. 9) having the seed zone OH1 (see FIG. 9) may also be transferred to the first device isolation layer 104, and in a subsequent process of separating the channel structures CHL, the step structure of the insulating layer OX (see FIG. 9) having the seed zone OH1 (see FIG. 9) and the first device isolation layer 104 may be used as a first planarization stop film and a second planarization stop film, respectively. Unlike a semiconductor memory device according to a comparative example, which is manufactured on a high-cost silicon on insulator (SOI) substrate, the semiconductor memory device 100 according to some implementations may be manufactured based on a general substrate without a separate insulating layer. Accordingly, the semiconductor memory device 100 may be manufactured with excellent reliability at a relatively low cost. In addition, because the step structure of the insulating layer OX (see FIG. 9) having the seed zone OH1 (see FIG. 9) and the first device isolation layer 104 may be used as the first planarization stop film and the second planarization stop film, respectively, in the subsequent process for separating the channel structures CHL, the variability of the channel structures CHL formed in the subsequent process may be reduced.

In FIGS. 1, 2, 3A and 3B, although the first device isolation layer 104 having the step portion 104 MS and the second device isolation layer 106 are illustrated as being arranged in the boundary region CPA, implementations are not limited thereto. For example, the device isolation layer that mutually insulates between the memory cells or the device isolation layer that mutually insulates between the memory cell region MCA and the peripheral circuit region PCA may also have a structure including the first device isolation layer having a step portion and the second device isolation layer.

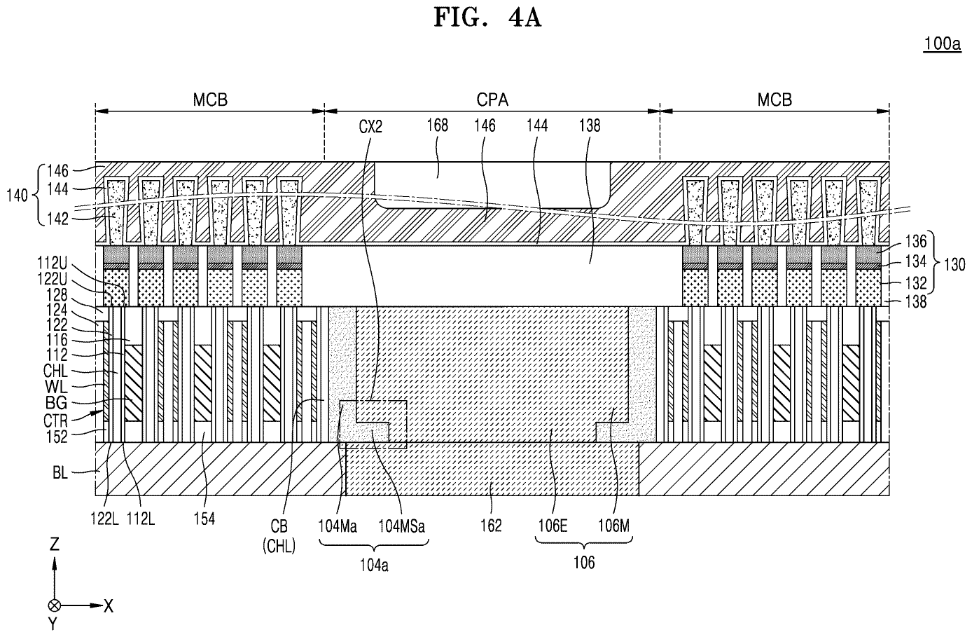

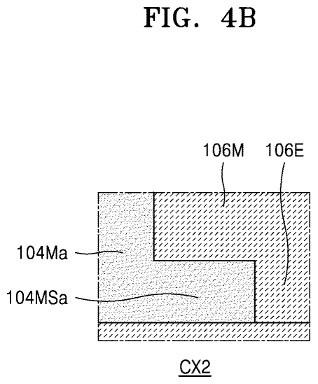

FIG. 4A is a cross-sectional view illustrating a semiconductor memory device 100a according to some implementations. FIG. 4B is an enlarged cross-sectional view of portion CX2 of FIG. 4A. Because the respective components of the semiconductor memory device 100a illustrated in FIGS. 4A and 4B are similar to the respective components of the semiconductor memory device 100 described above with reference to FIGS. 1, 2, 3A, and 3B, the following description focuses on the differences.

Referring to FIGS. 4A and 4B, the semiconductor memory device 100a may have a configuration substantially the same as or similar to that of the semiconductor memory device 100 described above with reference to FIGS. 1, 2, 3A, and 3B, except that the semiconductor memory device 100a includes a second portion 104Ma and a first device isolation layer 104a including a step portion 104MSa.

The first device isolation layer 104a included in the semiconductor memory device 100a may include the second portion 104Ma disposed on the conductive lines BL and the first interlayer insulating layer 162 on the boundary region CPA and the step portion 104MSa extending from an inner wall of the second portion 104Ma in the first horizontal direction (the X direction) and disposed on the first interlayer insulating layer 162. That is, the first device isolation layer 104a included in the semiconductor memory device 100a may not include the first portion 104E of the first device isolation layer 104 included in the semiconductor memory device 100 described above with reference to FIGS. 1, 2, 3A, and 3B. An upper surface of the second portion 104Ma may be in contact with the lower surface of the second interlayer insulating layer 138, and a lower surface of the second portion 104Ma may be in contact with the upper surfaces of the conductive lines BL and the upper surface of the first interlayer insulating layer 162. The second device isolation layer 106 may include the second portion 106M and the first portion 106E. Because the first device isolation layer 104a does not include a component corresponding to the first portion 104E (FIG. 3A), the first portion 106E may be placed on the first interlayer insulating layer 162, and the lower surface of the first portion 106E may be in contact with the upper surface of the first interlayer insulating layer 162. The lower surface of the second portion 104Ma of the first device isolation layer 104a and the lower surface of the first portion 106E of the second device isolation layer 106 may be positioned on the same plane. In addition, the lower surface of the second portion 104Ma of the first device isolation layer 104a may be positioned on the same plane as that of the lower surface of the channel structures CHL.

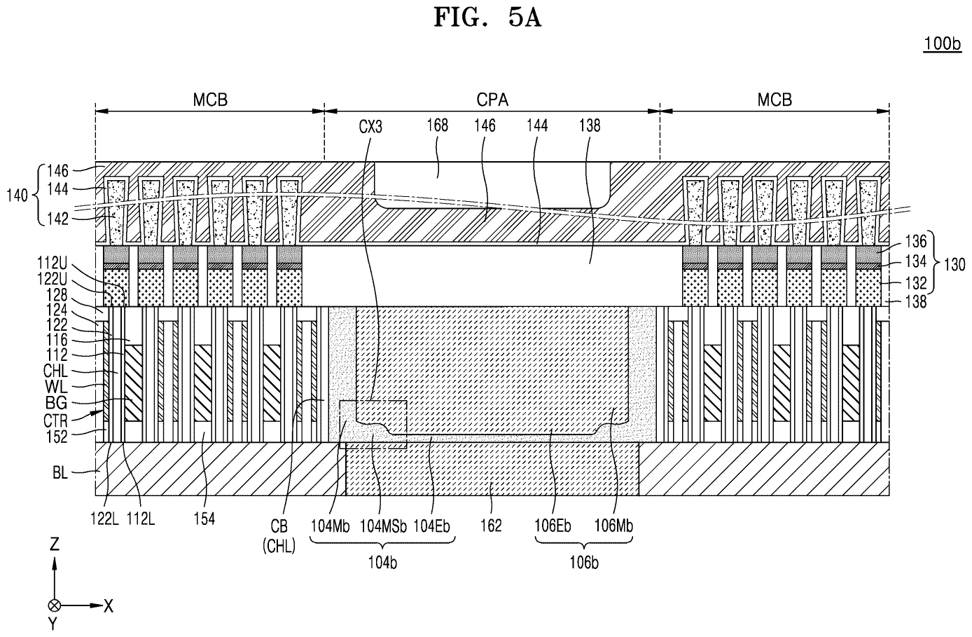

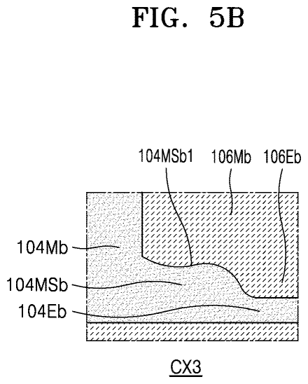

FIG. 5A is a cross-sectional view illustrating a semiconductor memory device 100b according to some implementations. FIG. 5B is an enlarged cross-sectional view of portion CX3 of FIG. 5A. Because the respective components of the semiconductor memory device 100b illustrated in FIGS. 5A and 5B are similar to the respective components of the semiconductor memory device 100 described above with reference to FIGS. 1, 2, 3A, and 3B, the following description focuses on the differences.

Referring to FIGS. 5A and 5B, the semiconductor memory device 100b may have a configuration substantially the same as or similar to that of the semiconductor memory device 100 described above with reference to FIGS. 1, 2, 3A, and 3B, except that the semiconductor memory device 100b includes a first device isolation layer 104b including a second portion 104Mb, a first portion 104Eb, and a step portion 104MSb and a second device isolation layer 106b including a second portion 106Mb and a first portion 106Eb.

The step portion 104MSb of the first device isolation layer 104b included in the semiconductor memory device 100b may have a curved inner wall 104MSb1. The curved inner wall 104MSb1 of the step portion 104MSb may be due to a nitride smoothing phenomenon that may occur when the first device isolation layer 104b is formed during the manufacturing process of the semiconductor memory device 100b. The curved inner wall 104MSb1 of the step portion 104MSb may be in contact with the first portion 106Eb of the second device isolation layer 106b.

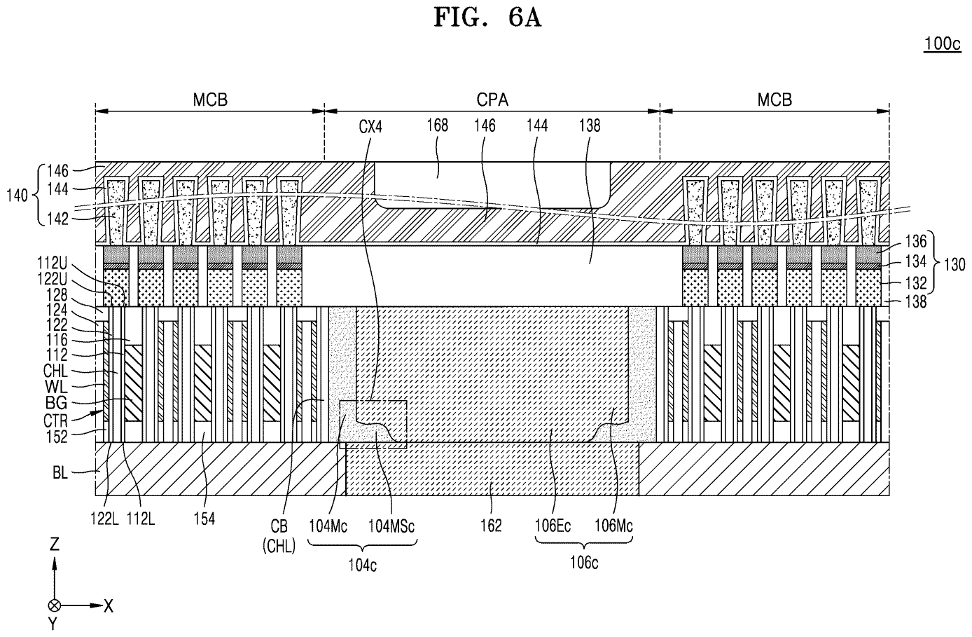

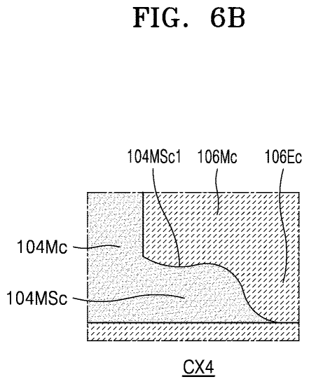

FIG. 6A is a cross-sectional view illustrating a semiconductor memory device 100c according to some implementations. FIG. 6B is an enlarged cross-sectional view of portion CX4 of FIG. 6A. Because the respective components of the semiconductor memory device 100c illustrated in FIGS. 6A and 6B are similar to the respective components of the semiconductor memory device 100 described above with reference to FIGS. 1, 2, 3A, and 3B, the following description focuses on the differences.

Referring to FIGS. 6A and 6B, the semiconductor memory device 100c may have a configuration substantially the same as or similar to that of the semiconductor memory device 100 described above with reference to FIGS. 1, 2, 3A, and 3B, except that the semiconductor memory device 100c includes a first device isolation layer 104c including a second portion 104Mc and a step portion 104MSc and a second device isolation layer 106c including a second portion 106Mc and a first portion 106Ec.

The first device isolation layer 104c included in the semiconductor memory device 100c may include the second portion 104Mc disposed on the conductive lines BL and the first interlayer insulating layer 162 on the boundary region CPA and the step portion 104MSc extending from an inner wall of the second portion 104Mc in the first horizontal direction (the X direction) and positioned on the first interlayer insulating layer 162. That is, the first device isolation layer 104c included in the semiconductor memory device 100c may not include the first portion 104E of the first device isolation layer 104 included in the semiconductor memory device 100 described above with reference to FIGS. 1, 2, 3A, and 3B. An upper surface of the second portion 104Mc may be in contact with the lower surface of the second interlayer insulating layer 138, and a lower surface of the second portion 104Mc may be in contact with the upper surface of the conductive lines BL and the upper surface of the first interlayer insulating layer 162. The second device isolation layer 106c may include the second portion 106Mc and the first portion 106Ec. Because the first device isolation layer 104c does not include a configuration corresponding to the first portion 104E (FIG. 3A), the first portion 106Ec may be placed on the first interlayer insulating layer 162, and the lower surface of the first portion 106Ec may be in contact with the upper surface of the first interlayer insulating layer 162.

The step portion 104MSc included in the first device isolation layer 104c may have a curved inner wall 104MScl. The curved inner wall 104MScl of the step portion 104MSb may be due to a nitride smoothing phenomenon that may occur when the first device isolation layer 104c is formed during the manufacturing process of the semiconductor memory device 100c. The curved inner wall 104Mcl of the step portion 104MSb may be in contact with the first portion 106Ec of the second device isolation layer 106c.

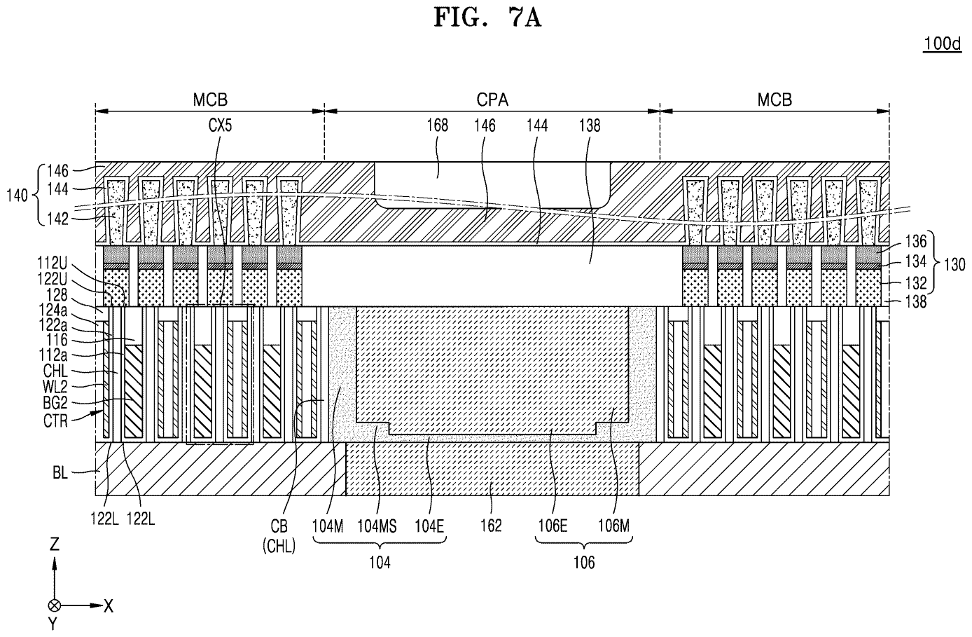

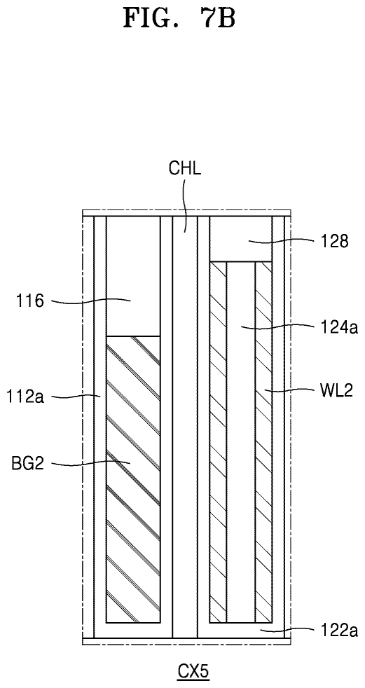

FIG. 7A is a cross-sectional view illustrating a semiconductor memory device 100d according to some implementations. FIG. 7B is an enlarged cross-sectional view of portion CX5 of FIG. 7A. Because the respective components of the semiconductor memory device 100d illustrated in FIGS. 7A and 7B are similar to the respective components of the semiconductor memory device 100 described above with reference to FIGS. 1, 2, 3A, and 3B, the following description focuses on the differences.

Referring to FIGS. 7A and 7B, the semiconductor memory device 100d may have a configuration substantially the same as or similar to the semiconductor memory device 100 described above with reference to FIGS. 1, 2, 3A, and 3B, except that the semiconductor memory device 100d includes a back gate electrode BG2, a back gate dielectric film 112a, an isolation insulating pattern 124a, a pair of word lines WL2, and a gate dielectric film 122a.

The semiconductor memory device 100d may not include a component corresponding to the second capping insulating pattern 154 and a component corresponding to the second buried insulating pattern 152 included in the semiconductor memory device 100 illustrated in FIG. 3A. Accordingly, the back gate electrodes BG2 and the word lines WL2 included in the semiconductor memory device 100d may extend relatively longer in the vertical direction (the Z direction) than the back gate electrodes BG and the word lines WL included in the semiconductor memory device 100 as illustrated in FIG. 3A, respectively.

The back gate dielectric film 112a may surround the surface of the back gate electrode BG2. For example, the back gate dielectric film 112a may surround opposite sidewalls of the back gate electrode BG2 and a bottom surface of the back gate electrode BG2. The back gate electrode BG2 may be apart from the channel structure CHL in the first horizontal direction (the X direction) with the back gate dielectric film 112a therebetween, and may be apart from the conductive line BL in the vertical direction (the Z direction) with the back gate dielectric film 112a therebetween.

The gate dielectric film 122a may surround the surface of the word line WL2. For example, the gate dielectric film 122a may surround the outer wall of each of a pair of word lines WL2 apart from each other in the first horizontal direction (the X direction) with the isolation insulating pattern 124a therebetween and the bottom surface of each of the pair of word lines WL2. Each of the pair of word lines WL2 may be apart from the conductive line BL in the vertical direction (the Z direction) with the gate dielectric film 122a therebetween.

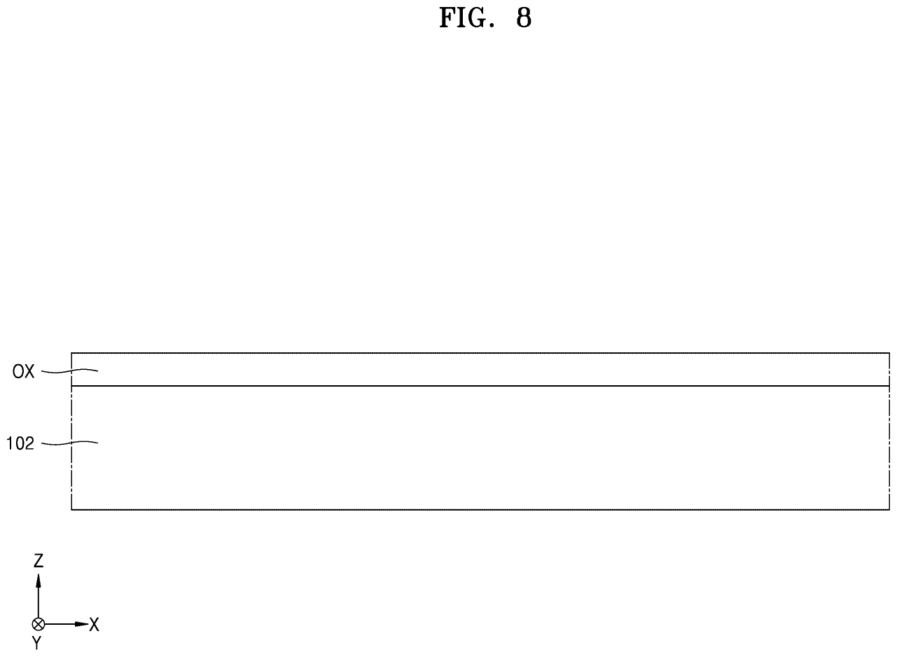

FIGS. 8 to 17 are cross-sectional views illustrating an example method of manufacturing the semiconductor memory device 100 according to some implementations.

Referring to FIG. 8, first, a substrate 102 may be prepared, and the insulating layer OX may be formed on an upper surface of the substrate 102. In some implementations, the substrate 102 may be a bulk substrate that does not include an insulating layer other than a silicon on insulator (SOI) substrate. In some implementations, the substrate 102 may include silicon, such as single crystal silicon, polycrystalline silicon, or amorphous silicon. In some implementations, the substrate 102 may include at least one selected from Ge, SiGe, SiC, GaAs, InAs, and InP. In some implementations, the substrate 102 may include a well doped with impurities or a structure doped with impurities.

The insulating layer OX may include, for example, an oxide. For example, the insulating layer OX may include a silicon oxide. The insulating layer OX may be formed through, for example, an ALD process, a CVD process, etc., but is not limited thereto.

Referring to FIG. 9, a seed zone OH1 may be formed by removing a central region of the insulating layer OX. The central region of the substrate 102 may be exposed by the seed zone OH1, and the insulating layer OX may have a step structure

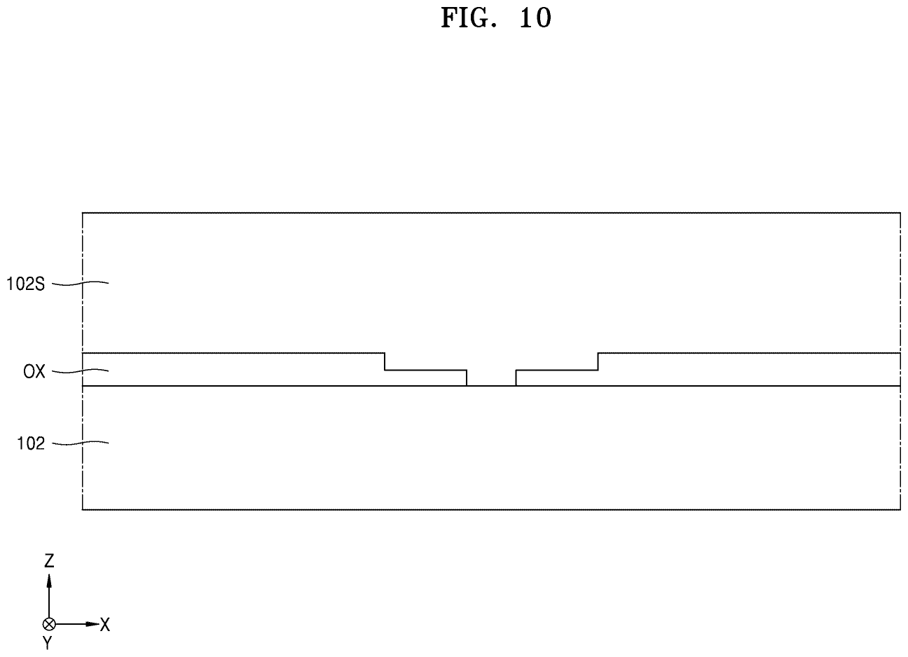

Referring to FIG. 10, a silicon layer 102S may be formed on the central region of the substrate 102 exposed by the insulating layer OX and the seed zone OH1 (see FIG. 9), and an upper surface of the formed silicon layer 102S may be planarized. In some implementations, the silicon layer 102S may be formed through epitaxial growth from the substrate 102 exposed by the seed zone OH1 (see FIG. 9).

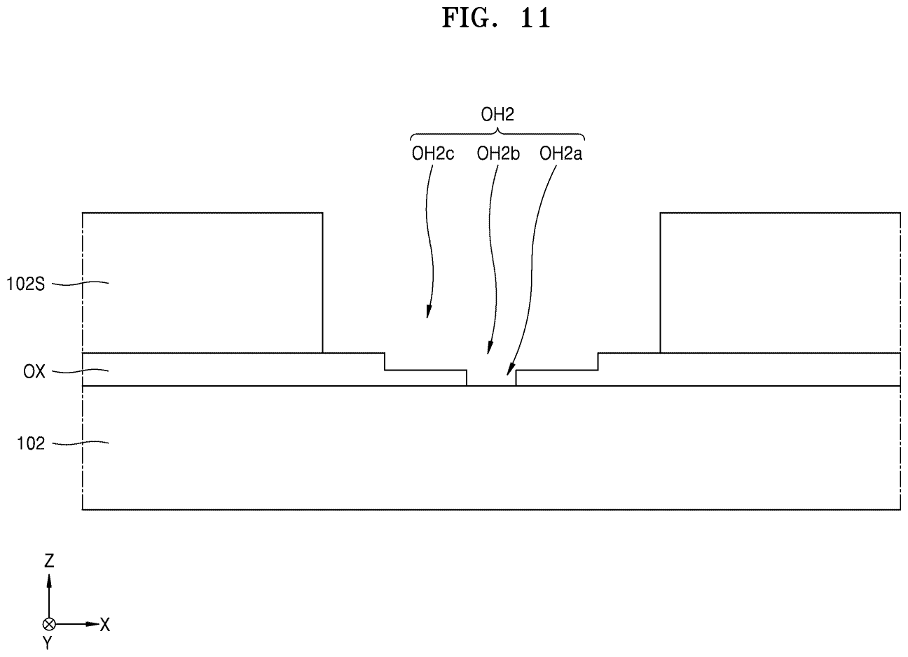

Referring to FIG. 11, an opening OH2 may be formed by removing the central region of the silicon layer 102S. The opening OH2 may be a region in which the first device isolation layer 104 and the second device isolation layer 106 are formed during the manufacturing process of the semiconductor memory device 100 described below. The opening OH2 may include a first opening OH2a, a second opening OH2b, and a third opening OH2c. The first opening OH2a may refer to a region of the opening OH2 that exposes the substrate 102. The second opening OH2b may be a region above the first opening OH2a and may have a wider horizontal width than the first opening OH2a. The third opening OH2c may be a region above the second opening OH2b and may have a wider horizontal width than the second opening OH2b.

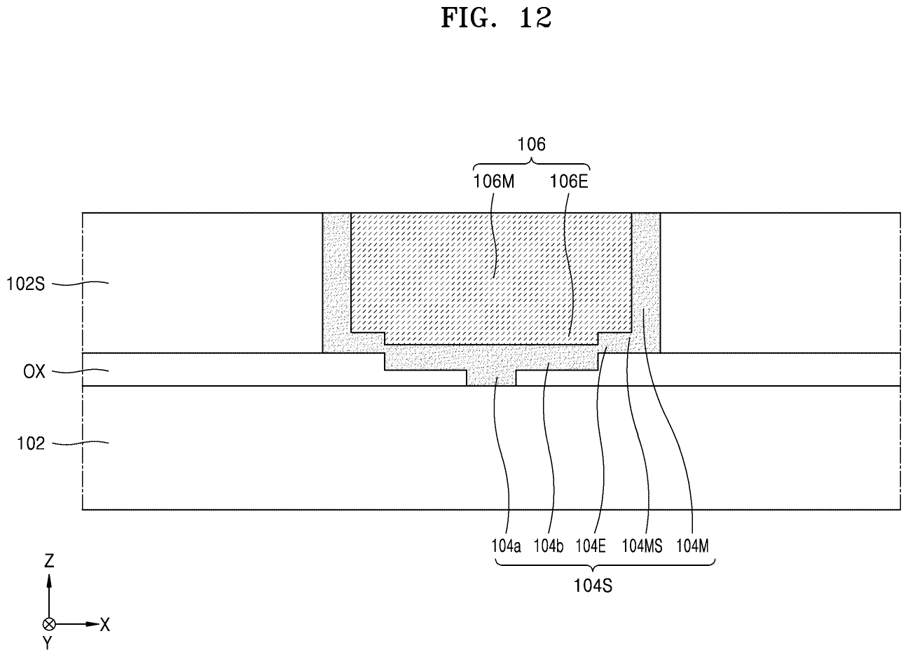

Referring to FIG. 12, the first device isolation material layer 104S and a second device isolation layer 106 may be formed to sequentially fill the opening OH2 (see FIG. 11). In some implementations, the first device isolation material layer 104S and the insulating layer OX may include different materials. For example, the first device isolation material layer 104S may include silicon nitride, and the insulating layer OX may include silicon oxide. In some implementations, the first device isolation material layer 104S and the second device isolation layer 106 may include different materials. For example, the first device isolation material layer 104S may include silicon nitride, and the second device isolation layer 106 may include silicon oxide. The first device isolation material layer 104S may include the first material layer 104a filling the first opening OH2a (see FIG. 11), the second material layer 104b filling the second opening OH2b (see FIG. 11), the first portion 104E filling the third opening OH2c, the second portion 104M, and the step portion 104 MS. The second device isolation layer 106 may include the first portion 106E disposed on the first portion 104E of the first device isolation material layer 104S and the second portion 106M disposed on the first portion 106E.

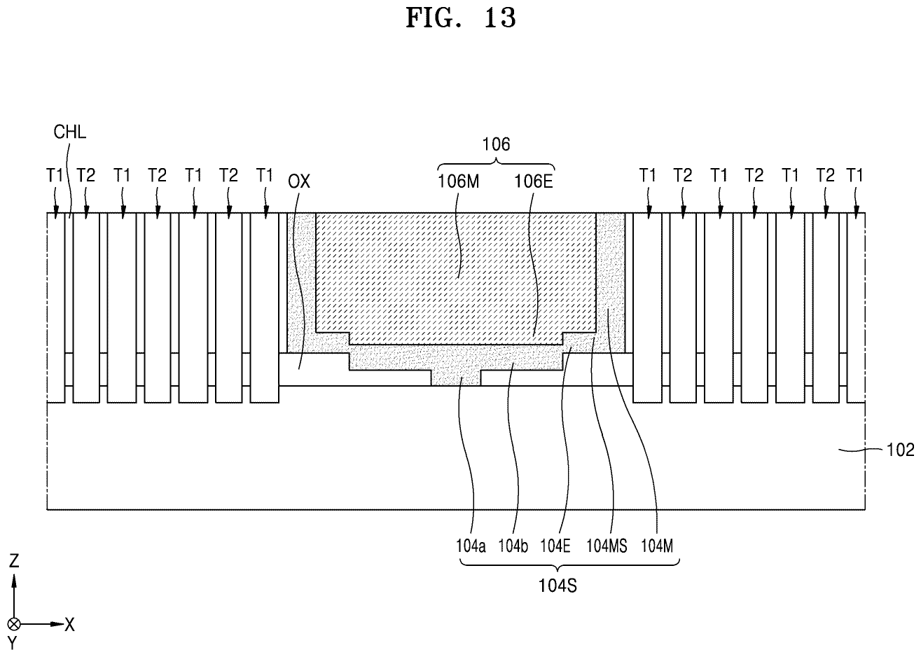

Referring to FIG. 13, after the opening OH2 (see FIG. 11) is formed, a plurality of first trenches T1 and a plurality of second trenches T2 extending through the remaining silicon layer 102S (see FIG. 12) and a portion of the insulating layer OX that overlaps the silicon layer 102S (see FIG. 12) in the vertical direction (the Z direction) and extending into the interior of the substrate 102 that overlaps the silicon layer 102S (see FIG. 12) in the vertical direction (the Z direction) may be formed. The first trench T1 and the second trench T2 may be formed alternately in the first horizontal direction (the X direction). The silicon layer 102S (see FIG. 12) remaining between the first trench T1 and the second trench T2 formed through the process illustrated in FIG. 13 may form the channel structure CHL of the semiconductor memory device 100 (see FIG. 3A). The first trench T1 may be a region in which the word line WL (see FIG. 3A) of the semiconductor memory device 100 is formed, as described below, and the second trench T2 may be a region in which the back gate electrode BG (see FIG. 3A) of a semiconductor memory device 100 is formed, as described below.

In some implementations, the first trenches T1 and the second trenches T2 may be formed to extend through the silicon layer 102S (see FIG. 12) remaining after the opening OH2 (see FIG. 11) is formed and a portion of the insulating layer OX that overlaps the silicon layer 102S (see FIG. 12) in the vertical direction (the Z direction). In this case, the bottom surface of each of the first trenches T1 and the second trenches T2 may expose a portion of the upper surface of the substrate 102.

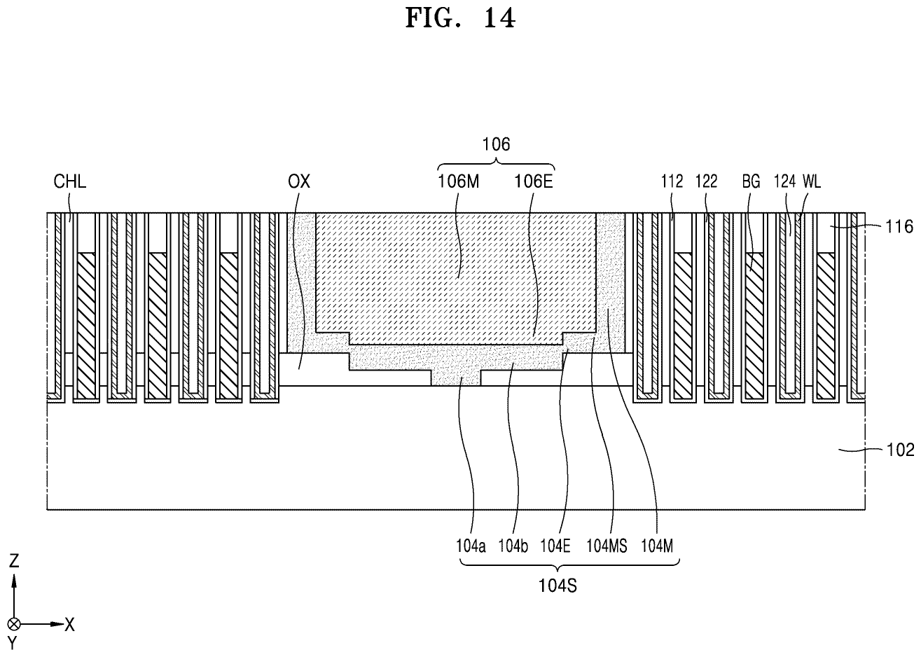

Referring to FIG. 14, the back gate dielectric film 112 filling the inner wall of the second trench T2 and the back gate electrode BG partially filling the internal space of the second trench T2 may be formed, the first capping insulating pattern 116 filling the upper space of the second trench T2 may be formed, and then the obtained result may be planarized.

Next, the gate dielectric film 122, the word line WL, and the isolation insulating pattern 124 may be formed to sequentially fill the inner wall of the first trench T1.

In some implementations, the isolation insulating pattern 124 may include a silicon oxide film.

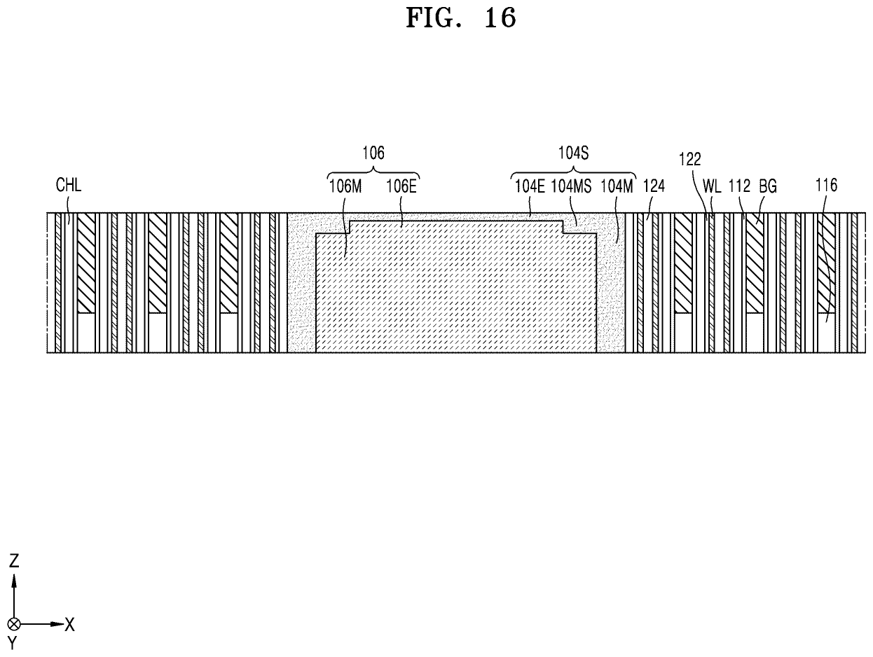

In some implementations, the isolation insulating pattern 124 may include a silicon nitride film. When the isolation insulating pattern 124 includes a silicon nitride film, in the second planarization process described below with reference to FIG. 16, the isolation insulating pattern 124 may function as a second planarization stop film together with the first portion 104E of the first device isolation layer 104.

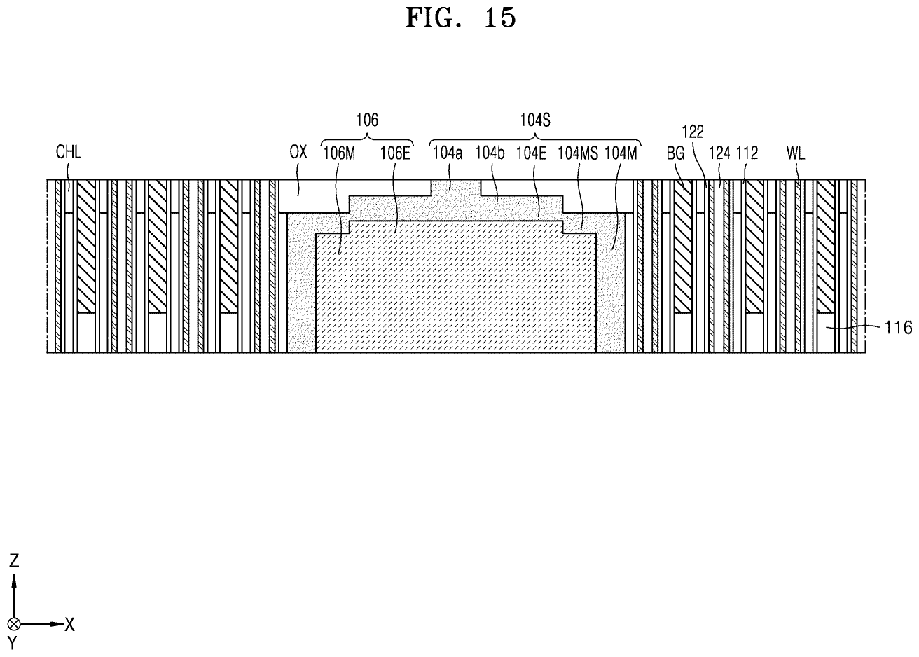

Referring to FIG. 15, the result obtained through the process illustrated in FIG. 14 may be flipped upside down so that the substrate 102 (see FIG. 14) faces upward in the vertical direction (the Z direction), and a first planarization process may be performed on the substrate 102 (see FIG. 14). The first planarization process may be, for example, a chemical mechanical polishing (CMP) process. In the first planarization process, one surface of the insulating layer OX in contact with the substrate 102 (see FIG. 14) may function as a stop film for the first planarization process. Accordingly, by the process illustrated with reference to FIG. 15, the substrate 102 (see FIG. 14) may be completely removed from one surface of the insulating layer OX, and one surface of each of the word line WL, the isolation insulating pattern 124, and the back gate electrode BG may be exposed.

Referring to FIG. 16, a second planarization process may be performed on the insulating layer OX. The second planarization process may be, for example, a CMP process. In some implementations, the second planarization process and the first planarization process illustrated in FIG. 15 may be performed under different conditions. In the second planarization process, one surface of the first portion 104E in contact with the second material layer 104b (scc FIG. 15) of the first device isolation material layer 104S (see FIG. 15) may function as a stop film of the above second planarization process. Accordingly, the insulating layer OX (see FIG. 15), the first material layer 104a (see FIG. 15), and the second material layer 104b (see FIG. 15) may be completely removed by the process illustrated with reference to FIG. 16. In addition, the first device isolation material layer 104S from which the first material layer 104a (see FIG. 15) and the second material layer 104b (see FIG. 15) are removed may be referred to as the first device isolation layer 104.

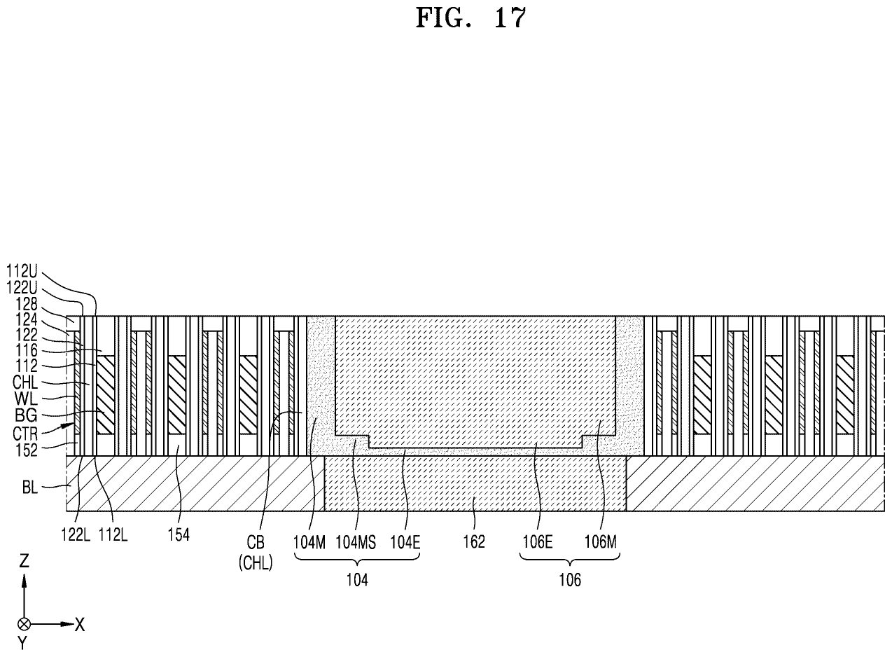

Referring to FIG. 17, a plurality of spaces may be provided by removing a portion of each of the exposed plurality of back gate electrodes BG and the word lines WL, and a plurality of second buried insulating patterns 152 and a plurality of second capping insulating patterns 154 may be formed to fill the spaces.

Next, the conductive lines BL covering the back gate dielectric films 112, the gate dielectric films 122, an isolation insulating pattern 124, the channel structures CHL, a plurality of second buried insulating patterns 152, and a plurality of second capping insulating patterns 154 and the first interlayer insulating layer 162 may be formed.

Next, in the result of FIG. 17, the result obtained through the process illustrated in FIG. 17 is flipped upside down so that the second device isolation layer 106 faces upward in the vertical direction (the Z direction) compared to the first device isolation layer 104, the contact plugs 130 are formed on the channel structures CHL, and the second interlayer insulating layer 138 that fills the space between each of the contact plugs 130 may be formed.

Thereafter, the capacitor structure 140 connected to the contact plugs 130 may be formed on the contact plugs 130 and the second interlayer insulating layer 138, thereby manufacturing the semiconductor memory device 100 as illustrated in FIGS. 1, 2, 3A, and 3B.

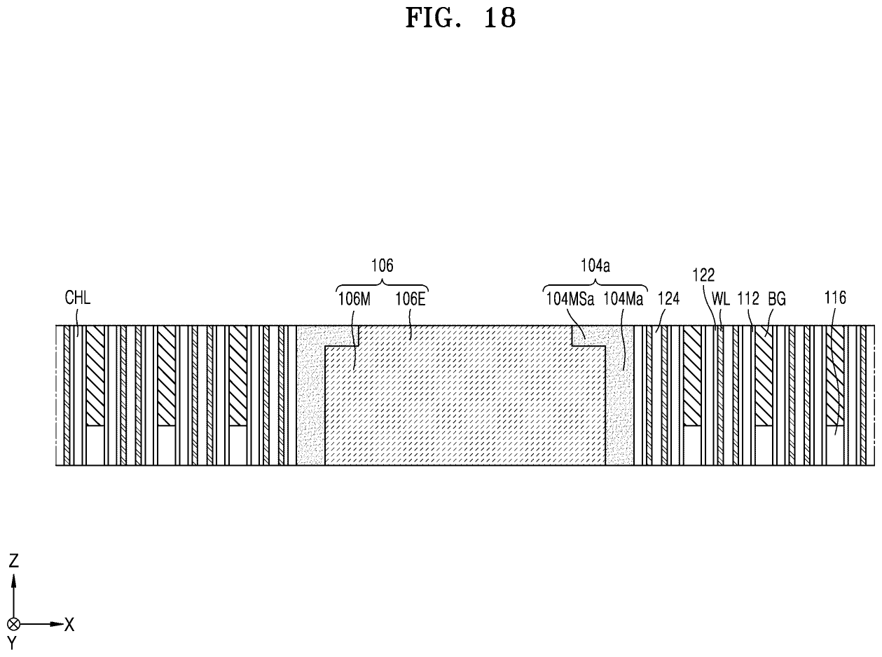

FIG. 18 is a cross-sectional view illustrating a method of manufacturing the semiconductor memory device 100a, according to some implementations.

Referring to FIG. 18, after the process described above with reference to FIGS. 8 to 15 is performed, a second planarization process for the insulating layer OX may be performed. The second planarization process may be, for example, a CMP process. In some implementations, the second planarization process may be performed under conditions different from those of the second planarization process illustrated in FIG. 16. In the above second planarization process, one surface of the first portion 106M of the second device isolation layer 106 in contact with the first portion 104E (see FIG. 15) of the first device isolation material layer 104S (see FIG. 15) may function as a stop film of the second planarization process. Accordingly, the insulating layer OX (see FIG. 15), the first material layer 104a (see FIG. 15), the second material layer 104b (see FIG. 15), and the first portion 104E (see FIG. 15) may be completely removed by the process illustrated with reference to FIG. 16. In addition, the first device isolation material layer 104S from which the first material layer 104a (see FIG. 15), the second material layer 104b (see FIG. 15) and the first portion 104E (see FIG. 15) are removed may be referred to as the first device isolation layer 104.

Next, after performing the process illustrated in FIG. 17, the result obtained through the process illustrated in FIG. 17 may be flipped upside down so that the second device isolation layer 106 faces upward in the vertical direction (the Z direction) compared to the first device isolation layer 104, the contact plugs 130 may be formed on the channel structures CHL, and the second interlayer insulating layer 138 may be formed to fill the space between each of the contact plugs 130.

Thereafter, the capacitor structure 140 connected to the contact plugs 130 may be formed on the contact plugs 130 and the second interlayer insulating layer 138, thereby manufacturing the semiconductor memory device 100a as illustrated in FIGS. 6A and 6B.

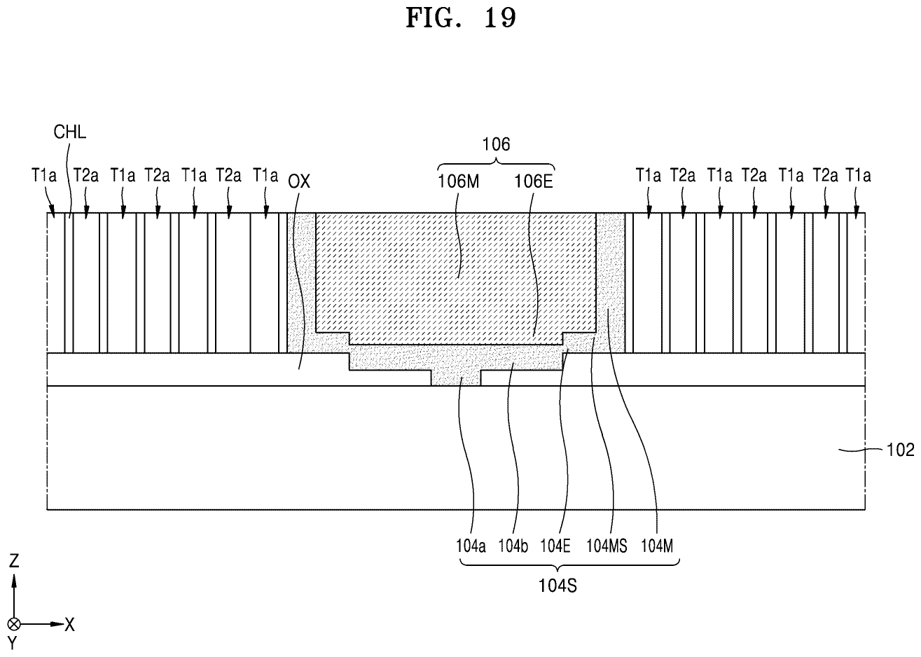

FIGS. 19 to 22 are cross-sectional views illustrating a method of manufacturing the semiconductor memory device 100d, according to some implementations.

Referring to FIG. 19, after the process described above with reference to FIGS. 8 to 12 is performed, the opening OH2 (see FIG. 11) may be formed, and the first trenches Tla and the second trenches T2a extending through the remaining silicon layer 102S (see FIG. 12) may be formed. That is, unlike the first trenches T1 and the second trenches T2a formed in the process illustrated in FIG. 13, the first trenches T1 and the second trenches T2 formed in the process illustrated in FIG. 19 may not extend through a portion of the insulating layer OX that overlaps the silicon layer 102S (see FIG. 12) in the vertical direction (the Z direction) and may not extend into the interior of the substrate 102 that overlaps the silicon layer 102S (see FIG. 12) in the vertical direction (the Z direction). The bottom surface of each of the first trenches Tla and the second trenches T2a may expose the insulating layer OX.

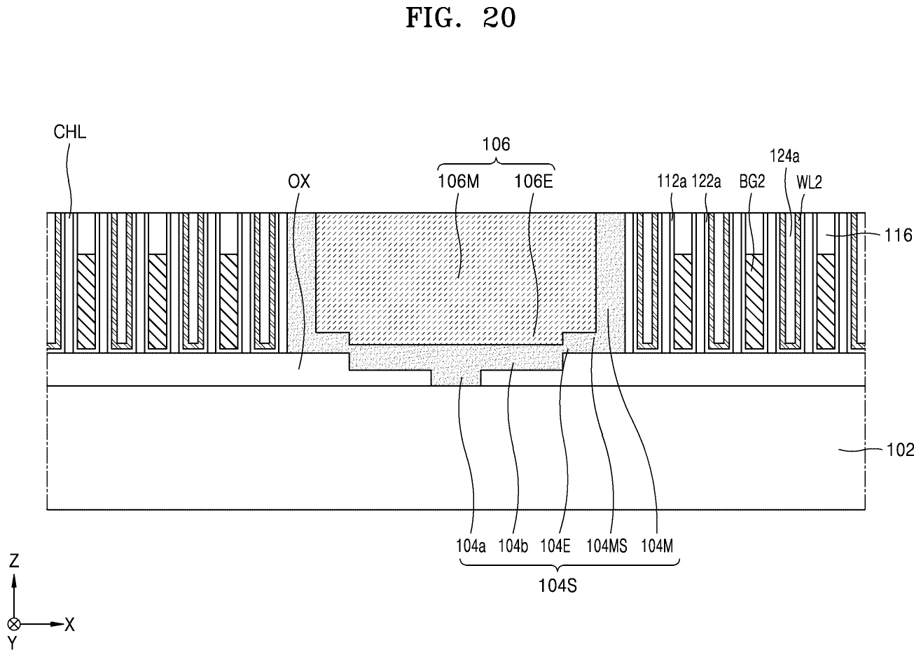

Referring to FIG. 20, the back gate dielectric film 112a filling the inner wall of the second trench T2a and the back gate electrode BG2 partially filling the internal space of the second trench T2 are formed, the first capping insulating pattern 116 filling the upper space of the second trench T2 is formed, and then the obtained result may be planarized.

Next, the gate dielectric film 122a, the word line WL2, and the isolation insulating pattern 124a may be formed to sequentially fill the inner wall of the first trench Tla.

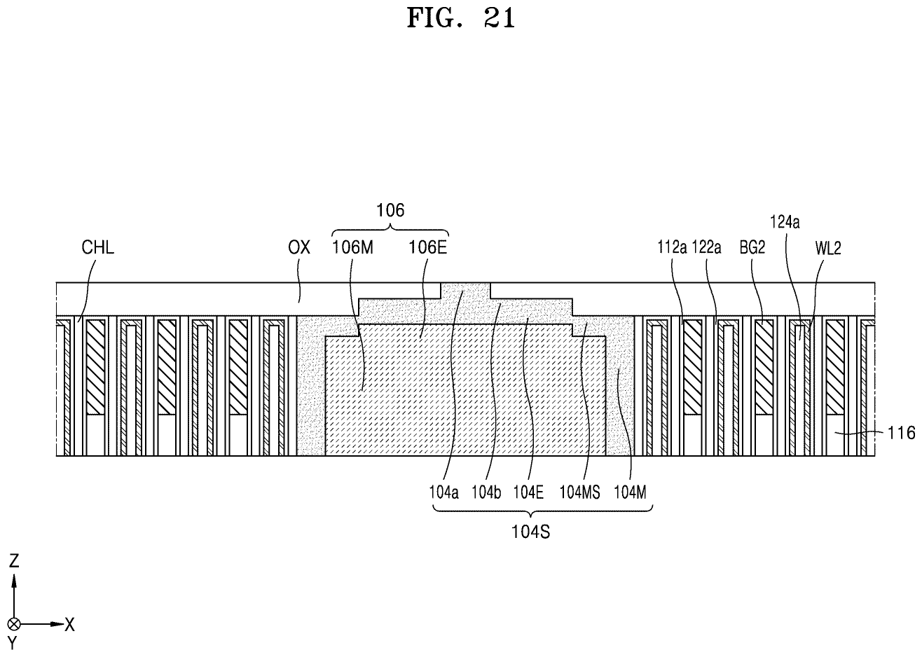

Referring to FIG. 21, the result obtained through the process illustrated in FIG. 20 may be flipped upside down so that the substrate 102 (see FIG. 20) faces upward in the vertical direction (the Z direction), and a first planarization process may be performed on the substrate 102 (see FIG. 20). The first planarization process may be, for example, a CMP process. In the first planarization process, one surface of the insulating layer OX in contact with the substrate 102 (see FIG. 20) may function as a stop film for the first planarization process. Accordingly, the substrate 102 (see FIG. 20) may be completely removed from one surface of the insulating layer OX by the process illustrated with reference to FIG. 15.

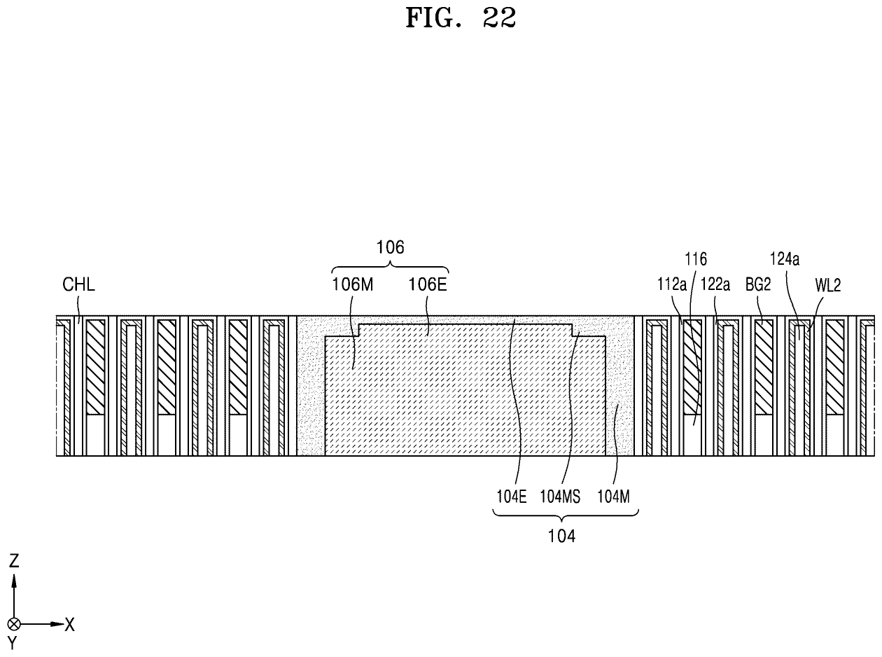

Referring to FIG. 22, a second planarization process may be performed on the insulating layer OX. The second planarization process may be, for example, a CMP process. In some implementations, the second planarization process may be performed under conditions different from those of the first planarization process illustrated in FIG. 21. In the second planarization process, one surface of the first portion 104E in contact with the second material layer 104b (see FIG. 21) of the first device isolation material layer 104S (see FIG. 21) may function as a stop film of the second planarization process. Accordingly, the insulating layer OX (see FIG. 21), the first material layer 104a (see FIG. 21), and the second material layer 104b (see FIG. 21) may be completely removed by the process illustrated with reference to FIG. 21. In addition, the first device isolation material layer 104S from which the first material layer 104a (see FIG. 21) and the second material layer 104b (see FIG. 21) are removed may be referred to as the first device isolation layer 104a. In addition, one surface of the back gate dielectric film 112a and one surface of the gate dielectric film 122a may be exposed by the process illustrated in FIG. 21.

Next, the process illustrated in FIG. 17 may be performed. Here, the conductive lines BL may be formed on one surface of the back gate dielectric film 112a and one surface of the gate dielectric film 122a, the back gate electrode BG2 may be apart from the conductive lines BL in the vertical direction (the Z direction) with the back gate dielectric film 112a therebetween, and the word line WL2 may be apart from the conductive lines BL in the vertical direction (the Z direction) with the gate dielectric film 122a therebetween.

Next, the result obtained through the process illustrated in FIG. 17 may be flipped upside down so that the second device isolation layer 106 faces upward in the vertical direction (the Z direction) compared to the first device isolation layer 104, the contact plugs 130 may be formed on the channel structures CHL, and the second interlayer insulating layer 138 may be formed to fill the space between each of the contact plugs 130.

Thereafter, the capacitor structure 140 connected to the contact plugs 130 may be formed on the contact plugs 130 and the second interlayer insulating layer 138, thereby manufacturing the semiconductor memory device 100d as illustrated in FIGS. 6A and 6B.

While this specification contains many specific implementation details, these should not be construed as limitations on the scope of any invention or on the scope of what may be claimed, but rather as descriptions of features that may be specific to particular some implementations of particular inventions. Certain features that are described in this specification in the context of separate some implementations can also be implemented in combination in a single implementation. Conversely, various features that are described in the context of a single implementation can also be implemented in multiple some implementations separately or in any suitable subcombination. Moreover, although features may be described above as acting in certain combinations, one or more features from a combination can in some cases be excised from the combination, and the combination may be directed to a subcombination or variation of a subcombination.

While the inventive concept has been particularly shown and described with reference to some implementations thereof, it will be understood that various changes in form and details may be made therein without departing from the spirit and scope of the following claims.

What is claimed is:

1. A semiconductor memory device comprising:
a plurality of memory cell blocks including a plurality of vertical channel transistors;
a boundary region surrounding each of the plurality of memory cell blocks and configured to insulate each of the memory cell blocks of the plurality of memory cell blocks from one another;
a first device isolation layer facing the plurality of vertical channel transistors in a first horizontal direction in the boundary region; and
a second device isolation layer apart from the plurality of vertical channel transistors in the first horizontal direction with the first device isolation layer therebetween,
wherein the first device isolation layer includes a first portion, a second portion disposed on the first portion, and a step portion disposed on the first portion and extending from an inner wall of the second portion to the second device isolation layer in the first horizontal direction.

2. The semiconductor memory device of claim 1, wherein the step portion has an upper surface in contact with the second device isolation layer and an inner wall in contact with the second device isolation layer, and the upper surface and the inner wall are flat surfaces.

3. The semiconductor memory device of claim 1, wherein the first device isolation layer and the second device isolation layer include different materials.

4. The semiconductor memory device of claim 1, wherein the second device isolation layer includes a first portion disposed on the first portion of the first device isolation layer and a second portion disposed on the first portion of the second device isolation layer.

5. The semiconductor memory device of claim 4, wherein
a lower surface of the second portion of the first device isolation layer and a lower surface of the first portion of the second device isolation layer are located at the same plane.

6. The semiconductor memory device of claim 1, wherein the step portion has an inner wall in contact with the second device isolation layer, and the inner wall is a curved surface.

7. The semiconductor memory device of claim 1, wherein
each of the plurality of vertical channel transistors includes:
a back gate electrode extending in a second horizontal direction intersecting the first horizontal direction;
a first channel structure and a second channel structure arranged on opposite sides of the back gate electrode in the first horizontal direction;
a word line spaced apart from a first side of the back gate electrode in the first horizontal direction, wherein the first channel structure is between the word line and the back gate electrode;
a back gate dielectric film between the first channel structure and the back gate electrode; and
a gate dielectric film between the first channel structure and the word line,
wherein
a bottom surface of the back gate dielectric film, a bottom surface of the gate dielectric film, and a lower surface of the first portion of the first device isolation layer are located at the same plane.

8. The semiconductor memory device of claim 7, wherein the back gate dielectric film covers a lower surface of the back gate electrode, and the gate dielectric film covers a lower surface of the word line.

9. The semiconductor memory device of claim 7, comprising, for each back gate electrode, an additional word line spaced apart from a second side of the back gate electrode in the first horizontal direction to form a conductive line group, wherein each conductive line group is spaced apart from an adjacent conductive line group in the first horizontal direction by an isolation insulating pattern.

10. The semiconductor memory device of claim 9, wherein the isolation insulating pattern includes a material that is different from the first device isolation layer.

11. The semiconductor memory device of claim 9, wherein the isolation insulating pattern includes a same material as that of the first device isolation layer.

12. A semiconductor memory device comprising:
a plurality of conductive lines extending in a first horizontal direction and spaced apart from each other in a second horizontal direction that is perpendicular to the first horizontal direction;
a first interlayer insulating layer surrounding the plurality of conductive lines;
a plurality of contact plugs arranged at positions spaced apart from the plurality of conductive lines in a vertical direction;
a second interlayer insulating layer surrounding the plurality of contact plugs;
a plurality of vertical channel transistors between the plurality of conductive lines and the plurality of contact plugs, the plurality of vertical channel transistors including a plurality of channel structures, each of the plurality of channel structures in contact with a respective one of the plurality of conductive lines and a respective one of the plurality of contact plugs;
a first device isolation layer between the first interlayer insulating layer and the second interlayer insulating layer and facing the plurality of vertical channel transistors in the first horizontal direction; and
a second device isolation layer apart from the plurality of vertical channel transistors in the first horizontal direction with the first device isolation layer therebetween,
wherein the first device isolation layer includes a first portion, a second portion positioned on the first portion, and a step portion positioned on the first portion and extending from an inner wall of the second portion to the second device isolation layer in the first horizontal direction.

13. The semiconductor memory device of claim 12, wherein the step portion has an upper surface in contact with the second device isolation layer and an inner wall in contact with the second device isolation layer, and the upper surface and the inner wall are flat surfaces.

14. The semiconductor memory device of claim 12, wherein the second device isolation layer includes a first portion positioned on the first portion of the first device isolation layer and a second portion positioned on a first portion of the second device isolation layer.

15. The semiconductor memory device of claim 14, wherein
a lower surface of the second portion of the first device isolation layer and a lower surface of the first portion of the second device isolation layer are located at the same plane.

16. The semiconductor memory device of claim 12, wherein the step portion has an inner wall in contact with the second device isolation layer, and the inner wall is a curved surface.

17. The semiconductor memory device of claim 12, wherein
each of the plurality of vertical channel transistors includes:
a back gate electrode extending in the second horizontal direction;
a first channel structure and a second channel structure arranged on opposing sides of the back gate electrode in the first horizontal direction;
a word line spaced apart from a first side of the back gate electrode in the first horizontal direction, wherein the first channel structure is between the word line and the back gate electrode;
a back gate dielectric film between the first channel structure and the back gate electrode; and
a gate dielectric film between the first channel structure and the word line,
wherein
a bottom surface of the back gate dielectric film, a bottom surface of the gate dielectric film, and a lower surface of the first portion of the first device isolation layer are located at the same plane.

18. The semiconductor memory device of claim 17, wherein the back gate dielectric film covers a lower surface of the back gate electrode, and the gate dielectric film covers a lower surface of the word line.

19. A semiconductor memory device comprising:
a memory cell region including a plurality of memory cell blocks and a boundary region surrounding the plurality of memory cell blocks; and
a peripheral circuit region surrounding the memory cell region,
wherein the semiconductor memory device comprises
a plurality of vertical channel transistors arranged in each of the plurality of memory cell blocks,
a first device isolation layer facing the plurality of vertical channel transistors in a first horizontal direction in the boundary region, and
a second device isolation layer apart from the plurality of vertical channel transistors in the first horizontal direction with the first device isolation layer therebetween, and
wherein the first device isolation layer includes a first portion, a second portion positioned on the first portion, and a step portion positioned on the first portion and extending from an inner wall of the second portion to the second device isolation layer in the first horizontal direction.

20. The semiconductor memory device of claim 19, wherein the first device isolation layer includes silicon nitride and the second device isolation layer includes silicon oxide.
